(19) United States
(12) Patent Application Publication
(10) Pub. No.: US 2021/0305072 A1
(43) Pub. Date: Sep. 30, 2021

(54) SUBSTRATE COOLING DEVICE

(71) Applicant: NISSIN ION EQUIPMENT CO., LTD., Koka City (JP)

(72) Inventors: Masatoshi ONODA, Koka City (JP); Ryosuke GOTO, Koka City (JP); Yoshiyuki NAKAZAWA, Koka City (JP)

(73) Assignee: NISSIN ION EQUIPMENT CO., LTD., Koka City (JP)

(21) Appl. No.: 17/193,302

(22) Filed: Mar. 5, 2021

(30) Foreign Application Priority Data
Mar. 24, 2020 (JP) 2020-52632

(51) Int. Cl. H01L 21/67; C23C 16/458; F28F 3/08

(52) U.S. Cl. CPC H01L 21/67109; F28F 3/086; C23C 16/4586

(57) ABSTRACT

A substrate cooling device is provided and includes a device body and a conduit block. The device body has a housing space, and a discharge portion for receiving and discharging a substrate into and out of the housing space. The conduit block includes an outlet port arranged in the device body across the housing space from the discharge portion, and a gas flow passage which is connected to the outlet port and receives a cooling gas. The conduit block outputs the cooling gas from the outlet port across the housing space in one direction such that the cooling gas flows across an upper surface of the substrate in the one direction and across a lower surface of the substrate in the one direction.

### CROSS-REFERENCE TO RELATED APPLICATION(S)

This application claims priority under 35 USC 119(a) of Japanese Patent Application No. 2020-52632 filed on Mar. 24, 2020 in the Japanese Patent Office, the entire disclosure of which is incorporated by reference herein in its entirety.

### BACKGROUND

### 1. Field

The present disclosure relates to a substrate cooling device, and more particularly to a substrate cooling device for cooling a substrate by a cooling gas.

### 2. Description of Related Art

Various types of substrates such as a semiconductor wafer and a glass substrate for flat-panel displays are typically cooled during manufacturing.

Generally, the presence of the difference in the progress of cooling between the surfaces of the substrate is likely to cause the occurrence of warpage in the substrate. Typically, a first surface of the substrate is cooled by a cooling plate, and a second surface opposite to the first surface is cooled by a cooling gas, so that it is possible to remove the difference in the progress of cooling between the first and second surfaces of the substrate, and uniformly cool the substrate. This makes it possible to suppress the occurrence of warpage in the substrate.

However, in the substrate cooled by respective different methods, there is a disadvantage in that it is difficult to control the different methods to remove the difference in the progress of cooling. Moreover, using multiple cooling methods requires the addition of components to implement multiple cooling methods resulting in an increase in structural complexity.

Another option is to use only a cooling gas. However, there is a disadvantage in that it is difficult to obtain even flow of the cooling gas over both surfaces of the substrate, resulting in difficulty in removing the difference in cooling between the two surfaces of the substrate and it is difficult to suppress the occurrence of warpage of the substrate.

Yet another option for cooling a semiconductor wafer after annealing includes introducing a cooling gas into a chamber housing plural substrates such that the cooling gas is supplied to flow between adjacent ones of the plurality of substrates. However, this method also does not take into account the difference in the progress of cooling between an upper side and an lower side of each of the substrates. Therefore, this method is also unable to uniformly cool the upper side and the lower side of the substrate, which is likely to raise the difference in the progress of cooling between the upper side and the lower side of the substrate, resulting in the occurrence of warpage in the substrate.

### SUMMARY

It is an aspect to provide a substrate cooling device capable of uniformly cooling a substrate by a cooling gas.

According to an aspect of one or more embodiments, there is provided a substrate cooling device comprising a device body having internally formed therein a housing space configured to house a substrate, the device body having a discharge portion formed therein; and a conduit block comprising a gas flow passage through which a cooling gas flows into the housing space, and an outlet port leading to the gas flow passage, the conduit block being configured to output the cooling gas such that the cooling gas flows along an upper surface of the substrate in one direction and along a lower surface of the substrate in the one direction, wherein the discharge portion is positioned across the substrate in opposed relation to the outlet port, and the cooling gas is discharged in the one direction from the housing space through the discharge portion.

According to an aspect of one or more embodiments, there is provided a substrate cooling device comprising a device body having a housing space, and a discharge portion for receiving and discharging a substrate into and out of the housing space; a conduit block comprising an outlet port arranged in the device body across the housing space from the discharge portion, and a gas flow passage which is connected to the outlet port and configured to receive a cooling gas, wherein the conduit block outputs the cooling gas from the outlet port across the housing space in one direction such that the cooling gas flows across an upper surface of the substrate in the one direction and across a lower surface of the substrate in the one direction.

According to an aspect of one or more embodiments, there is provided a substrate cooling device comprising a device body having a housing space including a support portion for supporting a substrate therein, the device body having an opening in a wall surface thereof; conduit block arranged in the device body across the housing space from the opening, the conduit block including a plurality of gas outlet ports and a gas flow passage in communication with the plurality of gas outlet ports, the gas flow passage configured to receive a cooling gas from outside of the substrate cooling device, wherein the cooling gas flows from the plurality of gas outlet ports, across the housing space, and out the opening in one direction such that the cooling gas flows in the one direction across an upper surface of the substrate when the substrate is supported by the support portion and in the one direction across a lower surface of the substrate.

### BRIEF DESCRIPTION OF DRAWINGS

The above and other aspects will be more clearly understood from the following detailed description, taken in conjunction with the accompanying drawings, in which:

FIG. 1 is a perspective view showing a substrate cooling device according to a first embodiment;

FIG. 2 is a top view of the substrate cooling device according to the first embodiment, in a state in which a cover member is detached therefrom;

FIG. 3 is a vertical sectional view of the substrate cooling device according to the first embodiment, taken along a line V1-V1 in FIG. 2;

FIG. 4 is an exploded perspective view showing a substrate cooling device according to a second embodiment;

FIG. 5 is a top view of the substrate cooling device according to the second embodiment, in a state in which a cover member is detached therefrom;

FIG. 6 is a vertical sectional view of the substrate cooling device according to the second embodiment, taken along a line V2-V2 in FIG. 5;

FIG. 7 is an exploded perspective view showing a substrate cooling device according to a third embodiment;

FIG. 8 is an exploded perspective view showing a conduit block in the substrate cooling device according to the third embodiment;

FIG. 9 is a top view of the substrate cooling device according to the third embodiment, in a state in which a cover member is detached therefrom;

FIG. 10 is a vertical sectional view of the substrate cooling device according to the third embodiment, taken along a line V3-V3 in FIG. 9;

FIG. 11 is a perspective view showing a conduit block in a modification of the third embodiment;

FIG. 12 is an exploded perspective view showing the conduit block in the modification of the third embodiment; and

FIG. 13 is a vertical sectional view of a substrate cooling device using the conduit block in the modification of the third embodiment.

### DETAILED DESCRIPTION

Generally, the presence of a difference in the progress of cooling between an upper surface and a lower surface of a substrate is likely to cause the occurrence of warpage in the substrate. A related art substrate cooling device typically includes a cooling plate which is disposed inside a processing chamber for housing a substrate, and internally formed with a cooling water path for circulating cooling water therethrough, and an air supply nozzle for supplying a cooling gas toward the substrate housed in the processing chamber. Further, proximity balls may be disposed on a surface of the cooling plate, such that, when the substrate is placed on the proximity balls, a gap is formed between the surface of the cooling plate and the substrate. The substrate cooling device is thus configured to cool a first surface of the substrate by the cooling plate, and to cool a second surface opposite to the first surface by the cooling gas output from the air supply nozzle. The first surface and the second surface of the substrate are cooled, respectively, by the cooling plate and the cooling gas, so that it is possible to remove the difference in the progress of cooling between the first and second surfaces of the substrate, and uniformly cool the substrate. This makes it possible to suppress the occurrence of warpage in the substrate.

However, since first surface and the second surface of the substrate are cooled by respective different methods, there is a problem of difficulty in control for removing the difference in the progress of cooling between the first and second surfaces of the substrate. Moreover, both a structure of the cleaning plate and a structure for supplying the cooling gas are required, thus increasing structural complexity of the entire device.

The related art substrate cooling device may configured such that the cooling gas flows on each of a first surface side and a second surface side of the substrate such that the two surfaces of the substrate may be cooled only by the cooling gas. However, this substrate cooling device is configured such that the cooling gas flows to go around from the upper side to the lower side of the substrate. Thus, if it is attempted to cool the substrate only by the cooling gas, the cooling gas after drawing heat on the upper side of the substrate will flow on the lower side of the substrate. Therefore, the substrate cooling device using only cooling gas is unable to remove a difference in cooling between the upper side and the lower side of the substrate. That is, the substrate cooling device using only cooling gas is unable to suppress the occurrence of warpage of the substrate.

It is also possible to cool a semiconductor wafer after annealing. Another related art substrate processing apparatus may a structure configured such that a boat holding a plurality of substrates is housed in a processing chamber, and a cooling gas is supplied to flow between adjacent ones of the plurality of substrates. However, the substrate processing apparatus simply supplies the cooling gas from an outlet port of a cooling gas supply nozzle toward the plurality of substrates, without taking into account the difference in the progress of cooling between the upper side and the lower side of each of the substrates. Therefore, the related art substrate processing apparatus is unable to uniformly cool the upper side and the lower side of the substrate, which is likely to raise the difference in the progress of cooling between the upper side and the lower side of the substrate, resulting in the occurrence of warpage in the substrate.

In the substrate cooling device according to embodiment described herein, a cooling gas output from an outlet port toward the substrate housed in a housing space flows on each of the upper surface and the lower surface of the substrate in one direction, and is then discharged from a discharge portion in the one direction. That is, the cooling gas output from the outlet port is discharged from the discharge portion after flowing on the upper surface and the lower surface of the substrate, in the one direction on a continuous basis. Thus, each of an upper surface side and a lower surface side of the substrate will be sequentially cooled from a region closer to the outlet port, so that it is possible to suppress a situation where a difference in the progress of cooling in the one direction occurs between the upper surface side and the lower surface side of the substrate. Therefore, it becomes possible to uniformly cool the substrate by the cooling gas.

Hereinafter, various embodiments will be described with reference to the accompanying drawings.

A substrate cooling device 10A according to a first embodiment, a substrate cooling device 10B according to a second embodiment, and a substrate cooling device 10C according to a third embodiment will be described.

Each of the substrate cooling devices 10A, 10B, 10C according to the first to third embodiments is a device for use in a semiconductor manufacturing process or a flat-panel display manufacturing process, and used in a state in which it is incorporated in a substrate processing apparatus for applying given processing to a substrate such as a semiconductor wafer or a glass substrate.

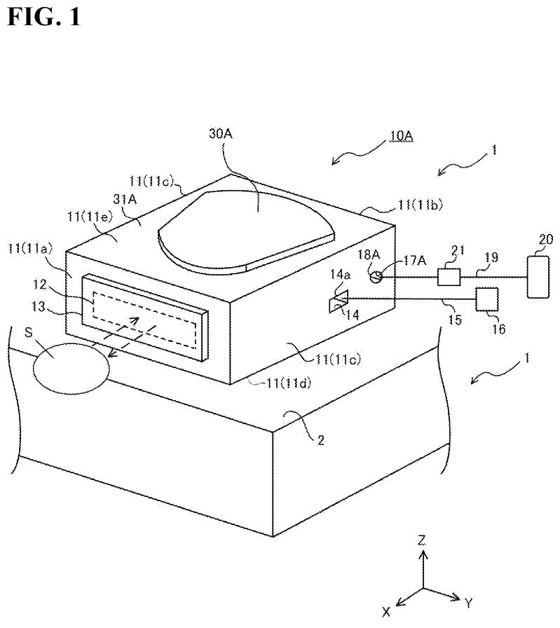

As shown in FIG. 1, the substrate cooling device 10A according to the first embodiment is installed to a disposition portion 2 of a substrate processing apparatus 1 and thus incorporated in the substrate processing apparatus 1. The substrate processing apparatus 1 in the first embodiment may be an ion implantation apparatus for subjecting a substrate S to ion implantation processing. The substrate S may be, for example, a semiconductor wafer. Further, in the description that follows, each of the substrate cooling devices 10B, 10C is used in a state in which the substrate cooling device 10B, 10C is installed to the disposition portion 2 of the substrate processing apparatus 1, in the same manner as that for the after-mentioned substrate cooling device 10A.

Here, the substrate processing apparatus 1 is not limited to an ion implantation apparatus, but may be any of various other substrate processing apparatuses such as a chemical vapor deposition (CVD) apparatus. Further, each of the substrate cooling devices 10A, 10B, 10C is not limited to being incorporated in the substrate processing apparatus 1, but may be used in a state in which it is placed, independently of the substrate processing apparatus 1.

### FIRST EMBODIMENT

The substrate cooling device 10A according to the first embodiment will be described. FIG. 1 is a perspective view showing the substrate cooling device 10A in a state in which it is assembled to the substrate processing apparatus 1. In FIG. 1, only a part of the substrate processing apparatus 1 is shown.

The substrate cooling device 10A is installed to the disposition portion 2 and thus incorporated in the substrate processing apparatus 1 which is an ion implantation apparatus, as mentioned above, and is a device configured to house a substrate S after being subjected to ion implantation processing, and cool the substrate S down to a target temperature. The substrate cooling device 10A also has a function as a load lock device configured such that the inside thereof is switchable between a state under high vacuum pressure and a state under atmospheric pressure. In other words, the substrate cooling device 10A may be regarded as a load lock device having a function of cooling the substrate S.

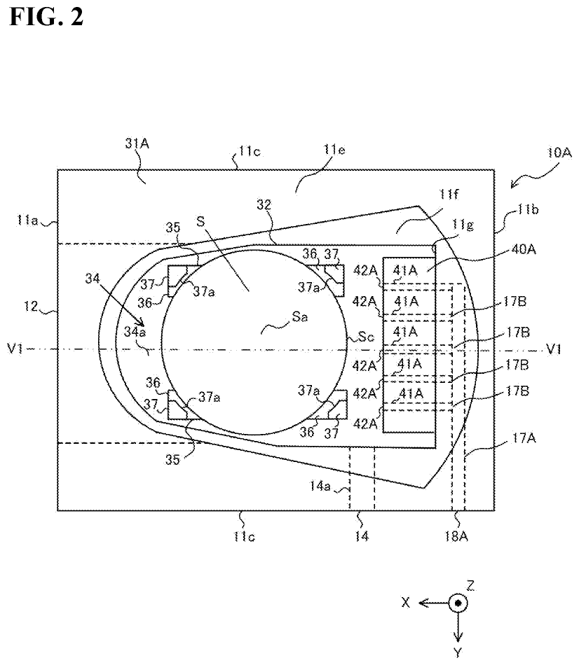

As shown in FIG. 1, the substrate cooling device 10A comprises a device body 31A internally formed with a housing space 34 for housing the substrate S, and a cover member 30A closing an opening 32 (see FIG. 2) formed in the device body 31A. Both the device body 31A and the cover member 30A are formed of a metal material. The device body 31A is configured such that the entire outline thereof is formed in a rectangular parallelepiped shape by a plurality of walls 11. The plurality of walls 11 consist of a front wall 11a, a rear wall 11b opposed to the front wall 11a, a pair of lateral walls 11c each coupling the front wall 11a and the rear wall 11b together, a bottom wall 11d and a ceiling wall 11e.

The front wall 11a is formed with a discharge portion 12 extending to penetrate through the front wall 11a in a thickness direction thereof and opened at both ends thereof. The discharge portion 12 is configured to discharge a cooling gas. In the substrate cooling device 10A, the discharge portion 12 is also used to take the substrate S in and out between the inside and outside of the device body 31A. More specifically, by a non-illustrated robot hand/arm, the substrate S may be transferred to pass through the discharge portion 12, such that the substrate S is carried in to the housing space 34 or carried out of the housing space 34.

It should be understood that, in some embodiments, the opening for taking the substrate S in and out may be formed at any position of the walls 11, separately from the discharge portion 12. Further, in some embodiments, an opening for carrying the substrate S in the housing space 34 and an opening for carrying the substrate S out of the housing space 34 may be provided separately.

The substrate cooling device 10A further comprises a flap valve 13 disposed outside the front wall 11a that is configured togas-tightly close the discharge portion 12. Further, one of the lateral walls, for example a lateral wall 11c, is formed with an evacuation hole 14 that penetrates the one of the lateral walls from the outside to the inside of the device body 31A. An evacuation pipe connecting section 14a is formed in an outer surface of the lateral wall 11c around an open end of the evacuation hole 14, and an evacuation pipe 15 leading to a vacuum pump 16 is connected to the evacuation pipe connecting section 14a. The vacuum pump 16 is an evacuating pump used for vacuuming or evacuating the inside of the device body 31. When the vacuum pump 16 is activated in a state in which the cover member 30A is attached to the device body 31A, and the flap valve 13 closes the exhaust portion 12, and air inside the device body 31A is evacuated to the outside of the device body 31A via the evacuation pipe 15, so that the inside of the device body 31A may be placed under high vacuum.

Here, the evacuation hole 14 and the evacuation pipe connecting section 14a are provided to allow the substrate cooling device 10A to additionally fulfill the function of the load lock device. In other words, in some embodiments in which the substrate cooling device 10A is configured with an aim only to house and cool the substrate S, it is not necessary to provide the evacuation hole 14 and the evacuation pipe connecting section 14a. That is, in some embodiments, the evacuation hole 14 and the evacuation pipe connecting section 14a may be omitted.

Further, one of the lateral walls, for example a lateral wall 11c, may be formed with a gas introduction hole 17A for allowing a cooling gas to flow therethrough, and a gas pipe connecting section 18A may be formed in the outer surface of the lateral wall around an open end of the gas introduction hole 17A. A gas pipe 19 leading to a gas source 20 for supplying the cooling gas is connected to the gas pipe connecting section 18A. A valve 21 is interposed in the gas pipe 19. Through a switching operation of the valve 21, it is possible to control supply of the cooling gas to the inside of the device body 31A.

Here, control of the supply of the cooling gas includes not only control of selectively starting and stopping the supply of the cooling gas, but also control of adjusting a flow volume and/or a flow velocity of the cooling gas. Further, such control may be performed automatically via a controller, or may be performed by an operator. In some embodiments, the cooling gas may be nitrogen gas. However, in other embodiments, the cooling gas may be an inert gas or dry air which does not exert any influence on various processings of the substrate S.

Further, it is not necessary that the cooling gas itself is cooled before being supplied to the inside of the device body 31A, as long as the cooling gas may cool the substrate S down to the target temperature. That is, in some embodiments, the cooling gas may have a temperature lower than the target temperature at a time immediately after being supplied to the inside of the device body 31A. When the target temperature is higher than normal temperature, the cooling gas may have normal temperature. For example, the normal temperature may be room temperature.

In the drawings and description that follows the assumption is that a horizontal plane is defined as an XY plane, and a vertical direction is defined as a Z-direction, wherein a direction along which the substrate S is taken in and out through the discharge portion 12 is aligned with the X-axis. As hereinafter used in this specification, the terms “front-rear (longitudinal) direction” and “right-left (lateral) direction” denote, respectively, a direction along the X-axis and a direction along the Y-axis, and the term “up-down (top-bottom) direction” denotes a direction along the Z-axis.

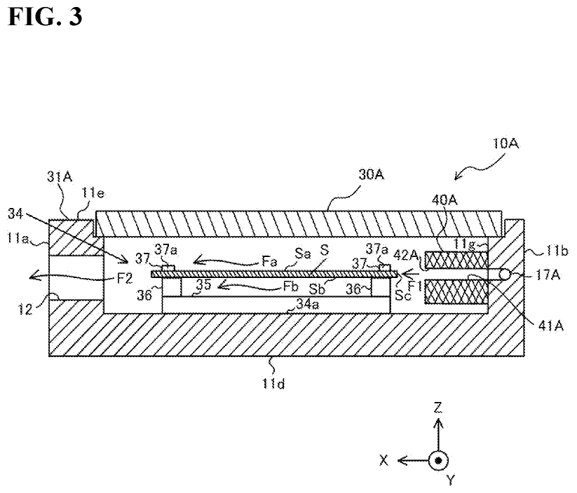

FIG. 2 is a top view of the substrate cooling device 10A in a state in which the cover member 30A is detached therefrom. FIG. 3 is a vertical sectional view of the substrate cooling device 10A, taken along a line V1-V1 in FIG. 2. It should be noted here that, in FIGS. 2 and 3, any component disposed on the outer side of the device body 31A, such as the flap valve 13, in FIG. 1, is omitted for conciseness. Further, whereas the cover member 30A is omitted in FIG. 2, it is shown in FIG. 3 without being omitted.

As shown in FIGS. 2 and 3, the device body 31A of the substrate cooling device 10A is internally formed with a housing space 34 for housing the substrate S. More specifically, the housing space 34 is a space defined by respective inner surfaces of the plurality of walls 11 disposed to surround the substrate S and making up the device body 31A, i.e., the front wall 11a, the rear wall 11b, the pair of lateral walls 11c, the bottom wall 11d, and the ceiling wall 11e, wherein as a result of attaching the cover member 31A the device body 31A, the housing space 34 is formed as a closed space with respect to the outside, except for the discharge portion 12.

As shown in FIGS. 2 and 3, the ceiling wall 11e is formed with a placement surface 11f for allowing the cover member 31A to be placed thereon.

The substrate S may be formed in a circular disk shape as a whole, and may have an upper surface Sa, a lower surface Sb, and a side surface Sc. However, the substrate S is not particularly limited, and in some embodiments may take different shapes. Here, various processings such as ion implantation may be applied to the upper surface Sa of the substrate S.

As shown in FIG. 2, a bottom wall inner surface 34a which is the inner surface of the bottom wall 11d defining the housing space 34 is formed with a plurality of mounting bases 35 for allowing the substrate S to be placed thereon. For example, two mounting bases 35 may be provided as a pair of mounting bases 35. The pair of mounting bases 35 may be formed to be spaced apart from each other in a right-left direction (Y-direction). As shown in FIG. 3, each of the mounting bases 35 may be formed to protrude upwardly from the bottom wall inner surface 34a, and have an elongate rectangular shape in top view. Further, each of the mounting bases 35 may be formed such that a lengthwise direction thereof is aligned with a front-rear direction (X-direction), and each of the lengthwise opposite ends of each of the mounting bases 35 may be provided with a support portion 36 for supporting the substrate S, and a restriction wall 37 having a restriction surface 37a for positioning the substrate S and restricting displacement of the substrate S. The pair of mounting bases 35 may form a gap between the lower surface Sb of the substrate S and the bottom wall inner surface 34a, to allow the cooling gas to smoothly flow frontwardly.

The pair of mounting bases 35 are configured to support the substrate S housed in the housing space 34, while forming a gap between the lower surface Sb of the substrate S and the bottom wall inner surface 34a to allow the cooling gas to flow therethrough. That is, the substrate S is not limited to being directly placed on the mounting bases 35, and in some embodiments, the substrate S may be placed on and supported by the support portions 36 provided on the mounting bases 35.

Here, the pair of mounting bases 35 may be provided to support the substrate S while lifting up the substrate S from the bottom wall inner surface 34a. Therefore, the mounting bases 35 may be provided by disposing separate members on the bottom wall inner surface 34a, or in some embodiments, may be integrally formed with the bottom wall inner surface 34a by subjecting the bottom wall inner surface 34a to cutting or the like. While two mounting bases 35 are described, embodiments are not limited to two and, in some embodiments, three or more mounting bases 35 may be provided.

Further, as shown in FIG. 2, the gas introduction hole 17A for allowing the cooling gas supplied from the gas source 20 to flow therethrough is formed to penetrate through the inside of the rear wall 11b constituting the device body 31A. More specifically, the gas introduction hole 17A is formed to extend from the gas pipe connecting section 18A formed in the outer surface of the lateral wall 11c, while being branched in mid-course at a plurality of branch points 17B, and lead to a plurality of open ends formed in the inner surface 11g of the rear wall 11b. For example, the gas introduction hole 17A may be found to branch in mid-course into four branch points 17B, and lead to five open ends formed in the inner surface 11g of the rear wall 11b.

As shown in FIGS. 2 and 3, the substrate cooling device 10A further comprises a conduit block 40A detachably disposed on the inner surface 11g of the rear wall 11b and configured to direct the cooling gas through the housing space 34. The conduit block 40A comprises a plurality of outlet ports 42A for outputting the cooling gas toward the substrate S housed in the housing space 34; and a plurality of gas flow passages 41A each formed to penetrate through the inside of the conduit block 40A in the front-rear direction and lead to a respective one of the outlet ports 42A and to allow the cooling gas to flow therethrough. For example, in some embodiments, five outlet ports 42A may be provided and five gas flow passages 41A may be provided. However, embodiments are not limited to five and in some embodiments more or fewer than five outlet ports and flow passages may be provided.

In the first embodiment, the conduit block 40A is configured to be detachable or removable with respect to the rear wall 11b among the walls 11. That is, in the substrate cooling device 10A according to the first embodiment, since the conduit block 40A is configured to be detachable from the rear wall 11b, the entire conduit block 40A may be removed to the outside of the device body 31A. Further, a disposition position of and an attaching method for the conduit block 40A with respect to the housing space 34 are not particularly limited, as long as the conduit block 40A is configured such that at least a part thereof is removable to the outside of the device body 31A. That is, the conduit block 40A may be composed of a plurality of constituent members, wherein the conduit block 40A may be configured such that at least one of the constituent members is removable to the outside of the device body 31A.

For example, in some embodiments, the conduit block 40A may be configured to be detachable with respect to the inner surface of one of the lateral walls 11c or the bottom wall 11d. Further, in some embodiments, the conduit block 40A may be attached while a sealing member such as packing is interposed between the conduit block 40A and one of the walls 11, or may be attached while a spacer member for adjusting the positions of the outlet ports 42A with respect to the substrate S is interposed therebetween.

As shown in FIGS. 2 and 3, each of the gas flow passages 41A of the conduit block 40A may formed to lead to a respective one of the open ends formed in the inner surface 11g of the rear wall 11b and leading to the gas introduction hole 17A. The outlet ports 42A and the gas flow passages 41A are configured such that a flow of the cooling gas output from the outlet ports 42A is uniformly formed, i.e., the cooling gas output from the outlet ports 42A are approximately fully uniform in terms of one or both of flow volume and flow velocity.

Here, when a path length and a number of the branch points 17B passing through from the gas introduction hole 17A to each of the outlet ports 42A are not the same, a flow rate and/or a flow velocity of the cooling gas from each outlet port 42A may be significantly different in some cases. In order to address this difference, in some embodiments, a configuration of the outlet ports 42A and the gas flow passages 41A may be modified to achieve uniformity in the flow of the cooling gas output from the outlet ports 42A. For example, in some embodiments, a position and shape of the outlet ports 42A and the gas flow passages 41A may be modified, e.g., by modifying a length, a passage diameter or shape, or location within the conduit block 40A of the gas flow passages 41A, the gas introduction hole 17A, and/or the branch points 17B. For example, in some embodiments, an opening area of one or more of the outlet port 42A may be adjusted with respect to each of the outlet ports 42A.

As shown in FIG. 3, the outlet ports 42A of the conduit block 40A are configured to output the cooling gas toward the side surface Sc of the substrate S, i.e., frontwardly (X-direction), and positioned in opposed relation to the side surface Sc of the substrate S housed in the housing space 34, at the same position as that of the substrate S in a thickness direction of the substrate S, i.e., in the up-down direction (Z-direction). As shown in FIG. 2, the outlet ports 42A are formed to be arranged in line at even intervals in the right-left direction (Y-direction). Further, the discharge portion 12 for discharging the cooling gas from the housing space 34 is formed such that the opening of discharge portion 12 is positioned in opposed relation to the outlet ports 42, across the substrate S. However, embodiments are not limited to this configuration and, in some embodiments, the outlet ports 42A may be positioned at uneven intervals (i.e., an unequal/uneven pitch), or may be positioned such that some outlet ports 42A are above the substrate S and some outlet ports 42A are below the substrate in the Z-direction (e.g., in a checkerboard type pattern). Moreover, in some embodiments, one or more of the outlet ports 42A may be closed.

Thus, the cooling gas output from the five outlet ports 42A is formed as a flow as shown in FIG. 3. The flow may include a first flow F1 and a second flow F2. The cooling gas is output from the outlet ports 42A frontwardly (X-direction), and thereby the first flow F1, which is a flow of the cooling gas immediately after being output from the outlet ports 42A, is generated. The first flow F1 is branched into an upper-side flow Fa which flows along the upper surface Sa of the substrate S and a lower-side flow Fb which flows along the lower surface Sb of the substrate S. After each of the upper-side flow Fa and the lower-side flow Fb flows on and across a corresponding one of the upper surface Sa and the lower surface Sb of the substrate S frontwardly, the upper-side flow Fa and the lower-side flow Fb are discharged to the outside of the housing space 34 through the discharge portion 12 in the form of a second flow F2, while a flow direction of the entirety of the upper-side flow and the lower-side flow Fa, Fb is maintained in the front direction.

In this way, the cooling gas flows on each of the upper surface Sa and the lower surface Sb of the substrate S in the front direction (X-direction), i.e., in one direction, as shown by the upper-side flow Fa and the lower-side flow Fb, and, in this process, draws heat from each of an upper surface Sa side and a lower surface Sb side of the substrate S to cool the substrate S. The cooling gas is kept flowing in the one direction, and discharged as the second flow F2. The side surface Sc of the substrate S is pushed by the first flow F1 frontwardly (X-direction). However, in the substrate housing device 10A according to the first embodiment, the displacement of the substrate S in the front direction is restricted by the restriction surface 37a formed in the restriction wall 37.

The operation of the substrate cooling device 10A according to the first embodiment will be described.

The substrate cooling device 10A may be used in a state in which the substrate cooling device 10A is incorporated in the substrate processing apparatus 1 which may be, for example, an ion implantation apparatus, and configured to cool the substrate S after the substrate S is subjected to ion implantation, and which serves as a load lock device. The substrate S is heated by a heating device (not-illustrated) equipped in the substrate processing apparatus 1, and subjected to ion implantation processing by irradiation with an ion beam in a processing chamber (not-illustrated) whose inside is set in high vacuum. The substrate S is housed in the housing space 34 of the device body 31A whose inside is set in high vacuum. The valve 21 is opened, and thereby the cooling gas starts to be supplied from the gas source 20 to the housing space 34. In some embodiments, the cooling gas is first supplied in a reduced flow volume, and output from the outlet ports 42A, so that the internal pressure of the housing space 34 is increased and then the valve 21 is further opened, and thereby the cooling gas is continuously introduced into the housing space 34 in a given flow volume or flow velocity set to sufficiently cool the substrate S.

As a result of the output of the cooling gas from the outlet ports 42A in the front direction (X-direction), the first flow F1 flowing frontwardly (X-direction) is generated. The first flow F1 is branched into the upper-side flow Fa and the lower-side flow Fb, and each of the upper-side flow Fa and the lower-side flow Fb flows on a corresponding one of the upper surface Sa and the lower surface Sb of the substrate S frontwardly in one direction (e.g., in the X-direction), whereafter the upper-side flow Fa and the lower-side flow Fb are formed as the second flow F2 and discharged frontwardly through the discharge portion 12 in the one direction (e.g., in the X-direction). The cooling gas is continuously supplied for a given time enough to cool the substrate S down to a desired temperature. The given time may be predetermined, or may be determined experimentally, and may be set different for different substrates S. After the elapse of the given time, the valve 21 is operated again to stop the supply of the cooling gas. Subsequently, the substrate S, which is now cooled, is carried outside the device body 31A through the discharge portion 12 by a non-illustrated robot hand. The flap valve 13 is closed, and the inside of the housing space 34 is vacuumed or evacuated by the vacuum pump 16 to return to the vacuum state.

In the first embodiment, the flap valve 13 is configured to be pushed frontwardly and opened by the second flow F2 while the cooling gas flows within the housing space 34. Alternatively, in some embodiments, the flap valve 13 may be configured such that opening and closing are controlled by a driving device such as a motor, as long as the opening and closing of the flap valve 13 does not hinder the flow of the cooling gas in the one direction during cooling of the substrate S.

In the substrate cooling device 10A according to the first embodiment, after the cooling gas is output from the outlet ports 42 toward the substrate S housed in the housing space 34, the cooling gas flows on each of the upper surface Sa and the lower surface Sb of the substrate S in the one direction, and is discharged from the discharge portion 12 in the one direction. That is, the cooling gas is discharged from the discharge portion 12 after flowing on the upper surface Sa and the lower surface Sb of the substrate S, in the one direction on a continuous basis, without going around from one surface side to the other surface side of the substrate and vice versa in a circular flow. In other words, the cooling gas flows straight from the outlet ports 42 to the discharge portion 12 in the one direction without forming a circular flow around the substrate S. Thus, each of the upper surface Sa side and the lower surface Sb side of the substrate S will be cooled from a region closer to the outlet ports 42A to a region farther from the outlet ports 42A, i.e., from the rear end to the front end of the substrate S in the X direction (see FIG. 3). This cooling makes it possible to suppress a situation where there is a top-down flow of cooling gas which creates a difference in the progress of cooling in between the upper surface Sa side and the lower surface Sb side of the substrate S. By cooling the substrate S from the rear end to the front end of the substrate S in the X direction according to the embodiment, it is possible to minimize a temperature difference between the upper surface Sa side and the lower surface Sb side of the substrate at any point on the wafer, thereby uniformly cooling the substrate with respect to the upper surface Sa side and the lower surface Sb side. Accordingly, no difference in the progress of cooling occurs between the upper surface Sa side and the lower surface Sb side in the Z direction, and thus the occurrence of warpage in the substrate S is suppressed. In other words, when the substrate S is cooled by a top-down flow in which the cooling gas is directed toward the center of the upper surface Sa side of the substrate S in the Z direction as in the related art, the cooling gas must flow around the ends of the substrate S to the lower surface Sb side of the substrate S, which creates a large temperature difference between the front side (facing the cooling gas) and back side of the substrate S and the substrate S cracks easily. A substrate S such as a wafer is typically a thin plate, and if there is some temperature difference between the front side and the back side of the wafer, the amount of shrinkage in the horizontal direction (X direction) on the front side and the back side will be different. This temperature difference easily causes warpage and cracking. Moreover, when the cooling gas is directed top-down toward a center of the upper surface Sa side of the substrate S, the cooling gas that has taken heat from the substrate S becomes turbulent, particularly near the ends of the substrate S, making cooling control difficult. By contrast, when the substrate S is cooled by a cooling gas that flows in one direction (X direction) as in the embodiments disclosed herein, the temperature between the front side and back side of the substrate S is more uniform and warpage and cracking may be reduced.

The first flow F1, the upper-side flow Fa and the lower-side flow Fb express a flow (i.e., an entire flow) of the entire cooling gas output from the outlet ports 42A. That is, each of the first flow F1, the upper-side flow Fa and the lower-side flow Fb may be formed as a flow spreading in the up-down direction or the right-left direction, or a turbulence flow, partly or microscopically, as long as the entire flow flows in the one direction as a whole.

In the substrate cooling device 10A according to the first embodiment, the plurality of outlet ports 42A are aligned at approximately the same position in the thickness direction of the substrate S, so that the first flow F1 is generated by the cooling gas output from the outlet ports 42A at approximately the same position in the thickness direction (i.e., the Z-direction in FIG. 3) of the substrate S. Thus, it is easy to form the first flow F1 uniformly in the right and left direction (Y-direction), i.e., in a direction orthogonal to the one direction (X-direction), on the upper surface Sa and the lower surface Sb of the substrate S. This confirmation makes it easy to form each of the upper-side flow Fa and the lower-side flow Fb uniformly in the right and left direction, i.e., in the direction orthogonal to the one direction, and thus form each of the upper-side flow and the lower-side flow uniformly in the orthogonal direction. That is, the occurrence of the difference in the progress of cooling may also be suppressed in the direction orthogonal to the one direction on the upper and lower surfaces of the substrate. In other words, it is possible to suppress the occurrence of the difference in the progress of cooling, even in the right and left direction, i.e., in the direction orthogonal to the one direction on the upper surface Sa and the lower surface Sb of the substrate S, thereby more uniformly cooling the substrate S.

In the substrate cooling device 10A according to the first embodiment, the first flow F1 may be branched into the upper-side flow Fa and the lower-side flow Fb by the side surface Sc of the substrate S, so that it is not necessary to divide the gas flow passages 41A formed in the conduit block 40A, into a group of flow passages for generating the upper-side flow Fa, and a group of flow passages for generating the lower-side flow Fb. Thus, the conduit block 40A may be formed with a simple structure.

Further, in the substrate cooling device 10A, it is not necessary to additionally provide a configuration for branching the first flow F1 into the upper-side flow Fa and the lower-side flow Fb. Thus, the configuration of the inside of the device body 31A may be simplified.

In the substrate cooling device 10A according to the first embodiment, the restriction wall 37 is provided to restrict the displacement of the substrate S in the one direction (X-direction). Thus, even when the side surface Sc of the substrate S is pushed by the first flow F1, the substrate S is prevented from being displaced beyond an allowable range.

In the substrate cooling device 10A according to the first embodiment, the conduit block 40A is configured to be removable to the outside of the device body 31A, so that the conduit block 40A may be removed to the outside of the device body 31A to perform maintenance work such as cleaning. Therefore, as comparted to a case where the conduit block 40A is integrally formed with the device body 31A, work efficiency during maintenance may be improved.

The conduit block 40A is not limited to the configuration in which the entirety of the conduit block 40A is removable to the outside of the device body 31A, but may be configured such that the conduit block 40A is composed of a plurality of members, wherein the members are partly removable to the outside of the device body 31A or where a portion of the members are removable to the outside of the device body 31A.

Further, suppose that the conduit block 40A is configured to be integrally formed with the device body 31A. In this case, for example, when it is desired to modify the outlet ports 42A or the gas flow passages 41A, it is necessary to replace the entire device body 31A. By contrast, in the substrate cooling device 10A according to the first embodiment, the entirety of or a part of the conduit block 40A may be replaced with a new one formed with outlet ports or a gas flow passages subjected to a desired modification. Therefore, it is possible to easily modify the configuration of the outlet ports 42A or the gas flow passages 41A.

For example, when it is desired to move the position of each of the outlet ports 42A closer to the substrate S, a conduit block produced such that each of the gas flow passages 41A is extended in the front direction to move the formation position of each of the outlet ports 42A closer to the substrate S may be used by swapping out the conduit block 40A and used.

### SECOND EMBODIMENT

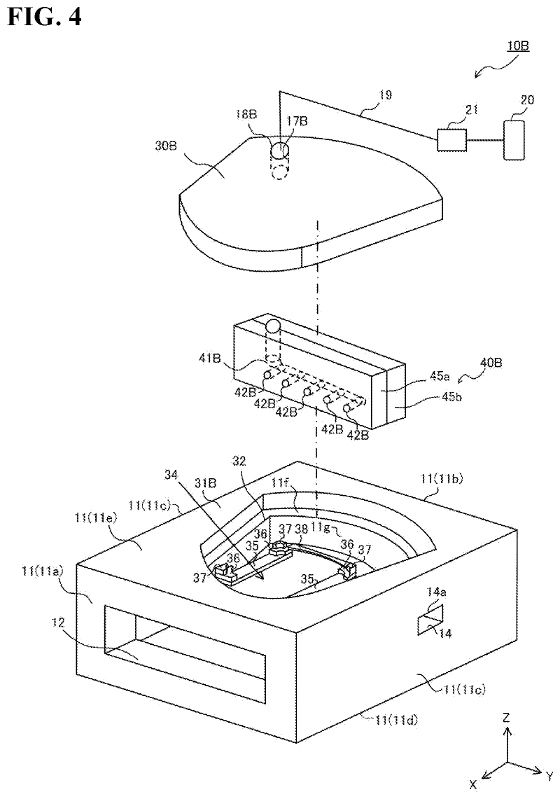

Next, the substrate cooling device 10B according to the second embodiment will be described with reference to FIGS. 4-6. In FIGS. 4 to 6, a common element or component with that in the substrate cooling device 10A according to the first embodiment is assigned with the same reference sign as that in the substrate cooling device 10A according to the first embodiment, and a repeated description thereof will be omitted for conciseness. Further, since the usage of the substrate cooling device 10B is identical to that of the substrate cooling device 10A, a repeated description of the usage will be omitted for conciseness. Thus, the following description will be made about configurations unique to the substrate cooling device 10B and functions/effects thereof

FIG. 4 is an exploded perspective view showing the substrate cooling device 10B according to the second embodiment. As shown in FIG. 4, the substrate cooling device 10B comprises a device body 31B internally formed with a housing space 34, and a cover member 30B covering an opening 32. Both the device body 31B and the cover member 30B may be formed of a metal material, and a conduit block 40B may be disposed on a lower surface of the cover member 30B and configured to flow out a cooling gas toward a substrate S housed in the housing space 34. That is, the substrate cooling device 10B is configured such that the conduit block 40B is disposed inside the device body 31A by attaching the cover member 30B to the device body 31A, and removed to the outside of the device body 31A by detaching the cover member 30B from the device body 31A.

With regard to the device body 31B and the cover member 30B, the device body 31B and the cover member 30B differ from the device body 31A and the cover member 30A in the substrate cooling device 10A according to the first embodiment in that a gas pipe connecting section 18B leading to a gas source 20, and a gas introduction hole 17B for allowing the cooling gas to flow therethrough, are formed in the cover member 30B. That is, the substrate cooling device 10B is configured such that the cooling gas supplied from the gas source 20 is introduced from the gas pipe connecting section 18B to the conduit block 40B mounted to the cover member 30B after passing through the gas introduction hole 17B, and output into the housing space 34 from a plurality of outlet ports 42B formed in the conduit block 40B.

As shown in FIG. 4, the gas introduction hole 17B is formed to penetrate through the cover member 30B in a thickness direction of the cover member 30B, and configured to lead to a gas flow passage 41B formed inside the conduit block 40B, in the state in which the conduit block 40B is attached to the cover member 30B.

The conduit block 40B comprises a first body 45a and a second body 45b, and comprises the plurality of outlet ports 42B, and the gas flow passage 41B branched halfway to lead to the outlet ports 42B. Each of the first body 45a and the second body 45b is formed with a groove or a through-hole which may be the gas flow passage 41B, wherein the gas flow passage 41B is created by combining the first body 45a and the second body 45b together.

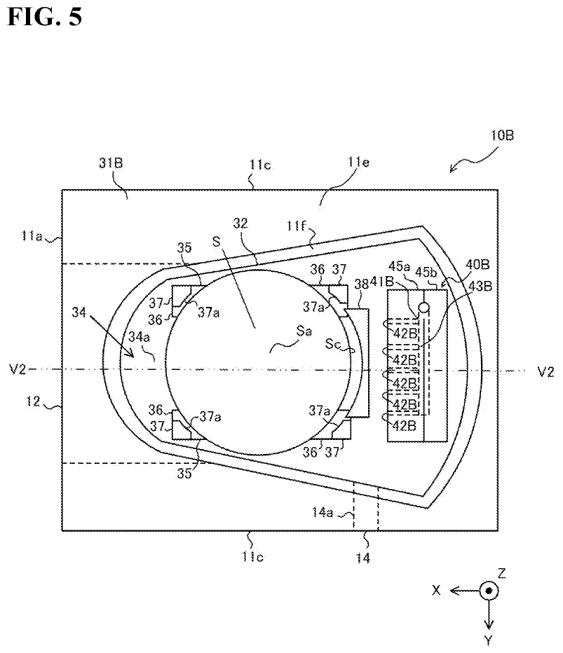

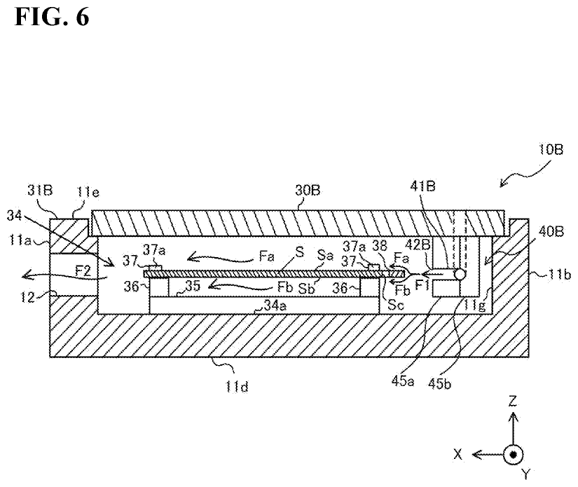

FIG. 5 is a top view of the substrate cooling device 10B in a state in which the cover member 30B is detached therefrom. FIG. 6 is a vertical sectional view of the substrate cooling device 10B, taken along the line V2-V2 in FIG. 5. Whereas the cover member 30B is omitted in FIG. 5, the cover member 30B is shown in FIG. 6. With regard to the conduit block 40B illustrated in FIG. 6, hatching is omitted for the sake of easy understanding of the figure. As shown in FIGS. 5 and 6, in the second embodiment, the conduit block 40B comprises the plurality of outlet ports 42B for outputting the cooling gas, and the gas flow passage 41B leading to the outlet ports 42B and for allowing the cooling gas to flow therethrough, wherein the conduit block 40B is disposed inside the housing space 34 in a state in which the conduit block 40B is detachably fixed to the cover member 30B. While five outlet ports 42B are illustrated in FIGS. 4-6, this is only an example, and in other embodiments, fewer or more than five outlet ports 42B may be provide. Further, the outlet ports 42B are formed at the same position in the up-down direction (Z-direction), such that the outlet ports 42B are opposed to a side surface Sc of the substrate S, and formed to be arranged in line in the right-left direction (Y-direction), as with the outlet ports 42A in the first embodiment.

As shown in FIGS. 4 to 6, the substrate cooling device 10B further comprises a branching member 38 that divides a first flow F1 into an upper-side flow Fa and a lower-side flow Fb. The branching member 38 may be formed of a thin plate, and attached to support portions 36 or to mounting bases 35 such that the branching member 38 is positioned between the outlet ports 42B and the substrate S housed in the housing space 34. For example, in some embodiments, the branching member 38 may be a deflector plate which deflects the first flow F1 into the upper-side flow Fa and the lower-side flow Fb.

Here, a positional relationship of the outlet ports 42B with respect to the substrate S is identical to that of the outlet ports 42A in the substrate cooling device 10A according to the first embodiment. Further, the flow of the cooling gas generated from the outlet ports 42B is also identical to that in the substrate cooling device 10A according to the first embodiment, except for the branching member 38 that helps the first flow F1 branch into the upper-side flow Fa and the lower-side flow Fb, and therefore a repeated description of the flow will be omitted for conciseness. In some embodiments, the branching member 38 may be incorporated into the substrate cooling device 10A according to the first embodiment.

In the substrate cooling device 10B according to the second embodiment, the gas introduction hole 17B may be formed by piercing the cover member 30B in the thickness direction (Z-direction) thereof. Thus, the formation of the gas introduction hole 17B is facilitated, as compared with a case where the gas introduction hole 17A is formed in one of the walls 11 of the device body 31A, as in the substrate cooling device 10A according to the first embodiment.

On the other hand, although the formation of the gas introduction hole 17B is facilitated as compared with the substrate cooling device 10A according to the first embodiment, the structure of the gas flow passage 41B formed inside the conduit block 40B becomes more complex due to an increased number of branched portions, which may cause difficulty in formation of the conduit block 40B. As a measure against this problem, the conduit block 40B in the second embodiment may be configured such that the gas flow passage 41B is created by combining the first body 45a and the second body 45b together, after forming, in each of the first body 45a and the second body 45b, a groove or a through-hole which may be the gas flow passage 41B for allowing the cooling gas to flow therethrough. Thus, By forming a groove or a through-hole which may be the gas flow passage 41B, in each of the first body 45a and the second body 45b, it is possible to easily form the gas flow passage 41B even when a final shape thereof is complicated.

In the second embodiment, the conduit block 40B includes two bodies, and the gas flow passage 41B is formed by combining the first body 45a and the second body 45b together. However, this is only an example, and in some embodiments, the conduit block 40B may include three or more bodies. Further, in some embodiments, a sealing member may be interposed between the bodies to provide enhanced gas-tightness.

The substrate cooling device 10B is configured to branch the first flow F1 into the upper-side flow Fa and the lower-side flow Fb by the branching member 38, so that the first flow F1 may be branched into the upper-side flow Fa and the lower-side flow Fb such that the first flow F1 does not push the substrate S in the front direction (X-direction), and therefore there is no possibility of the occurrence of displacement of the substrate S due to the first flow F1. Thus, without taking into account the occurrence of displacement of the substrate S, one or both of the flow velocity and flow volume of the first flow F1 may be increased, thereby improving the efficiency of cooling of the substrate S. That is, it is possible to shorten a time period for cooling the substrate S down to a given temperature. As a result, in a substrate processing apparatus 1 using the substrate cooling device 10B, the entire time period of processing for the substrate S may be shortened to provide improved throughput.

In the second embodiment, since there is no possibility of the occurrence of displacement of the substrate S, in some embodiments, the restriction wall 37 in the first embodiment may be omitted.

As shown in FIG. 6, the conduit block 40B is disposed in the housing space 34 in a state in which a gap is formed between the conduit block 40B and a bottom wall inner surface 34a, and a gaps is formed between the conduit block 40B and an inner surface 11g of a rear wall 11b. Thus, during the attachment of the cover member 30B to the device body 31B, the cover member 30B having the conduit block 40B fixed thereto may be moved downwardly and attached to the device body 31B. In the attachment process, the conduit block 40B less likely to contact the bottom wall inner surface 34a and the inner surface 11g. That is, damage or particle generation caused by contact of the conduit block 40A with the bottom wall inner surface 34a or the inner surface 11g may be suppressed.

### THIRD EMBODIMENT

Next, the substrate cooling device 10C according to the third embodiment will be described.

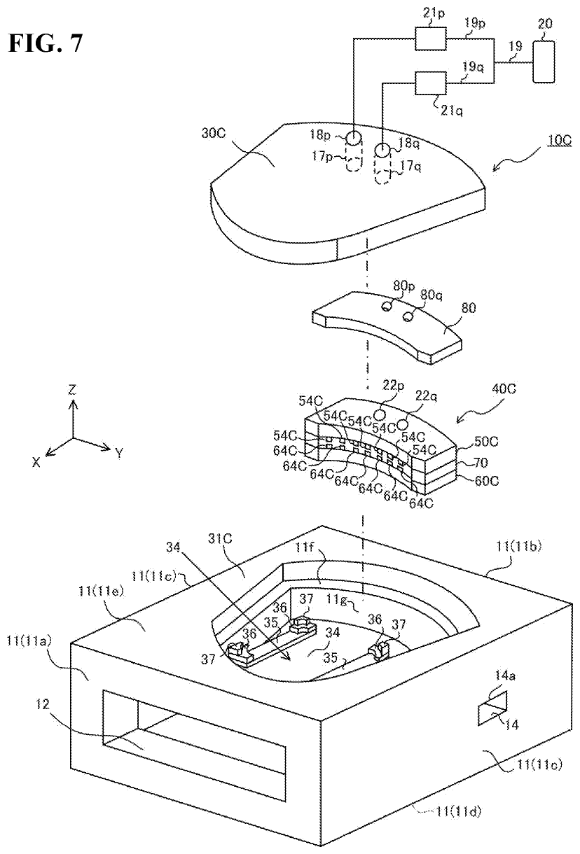

In FIGS. 7 to 10, a common element or component with that in the substrate cooling device 10A according to the first embodiment or the substrate cooling device 10B according to the second embodiment is assigned with the same reference sign as that in the substrate cooling device 10A according to the first embodiment and the substrate cooling device 10B according to the second embodiment, and repeated descriptions thereof will be omitted for conciseness. Further, since the usage of the substrate cooling device 10C is identical to that of the substrate cooling device 10A, a repeated description of the usage will be omitted for conciseness. Thus, the following description will be made about configurations unique to the substrate cooling device 10C and functions/effects thereof.

FIG. 7 is an exploded perspective view showing the substrate cooling device 10C according to the third embodiment.

As shown in FIG. 7, the substrate cooling device 10C comprises a device body 31C, a cover member 30C that is configured to be attached to the device body 31C, a conduit block 40C that direct a cooling gas through the housing space 34, and a spacer member 80 disposed between the cover member 30C and the conduit block 40C. In some embodiments, each of the device body 31C, the cover member 30C, the conduit block 40C and the spacer member 80 may be formed of a metal material.

The conduit block 40C comprises an upper-side flow passage member 50C, an intermediate member 70 and a lower-side flow passage member 60C. Each of the upper-side flow passage member 50C, the intermediate member 70 and the lower-side flow passage member 60C may have a plate shape, wherein the upper-side flow passage member 50C, the intermediate member 70 and the lower-side flow passage member 60C are assembled such that the upper-side flow passage member 50C, the intermediate member 70 and the lower-side flow passage member 60C are stacked in the up-down direction (Z-direction), i.e., in a thickness direction thereof

The intermediate member 70 has a plurality of upper-side outlet ports 54C for generating an upper-side flow Fa flowing on an upper surface Sa of a substrate S housed in a housing space 34, and a plurality of lower-side outlet ports 64C for generating a lower-side flow Fb flowing on a lower surface Sb of the substrate S. While seven upper-side outlet ports 54C and seven lower-side outlet ports 64C are illustrated in FIGS. 7-10, this is only an example and, in other embodiments, fewer or more than seven upper-side outlet ports 54C and fewer or more than seven lower-side outlet ports 64C may be provided. Each of the upper-side outlet ports 54C and the lower-side outlet ports 64C is formed of an opening whose periphery is closed, by combining the upper-side flow passage member 50C and the lower-side flow passage member 60C with the intermediate member 70. In other words, the upper-side flow passage member 50C closes the upper-side outlet ports 54C and the lower-side flow passage member 60C closes the lower-side outlet ports 64C.

In the third embodiment, the shape of each open end of the upper-side outlet ports 54C and the lower-side outlet ports 64C may be a rectangular shape. However, the shape is not limited to a rectangular shape, and in some embodiments, the shape may be any other suitable shape such as a round shape. Further, all the upper-side outlet ports 54C and the lower-side outlet ports 64C need not necessarily have the same shape and, in some embodiments, the upper-side outlet ports 54C and the lower-side outlet ports 64C may have different shapes.

In the third embodiment, the conduit block 40C is configured to be removable to the outside of the device body 31A by detaching the cover member 30C from the device body 31A. Alternatively, the conduit block 40C may be configured such that any one of the upper-side flow passage member 50C, the intermediate member 70 and the lower-side flow passage member 60C may be removed from the device body 31A, separately.

The substrate cooling device 10C according to the third embodiment may comprise a single gas source 20 and a gas pipe 19, as with the substrate cooling device 10A according to the first embodiment, but the gas pipe 19 may be branched halfway into an upper-side gas pipe 19p and a lower-side gas pipe 19q. Further, the cover member 30C is formed with a first gas pipe connecting section 18p and a second gas pipe connecting section 18q, and a first gas introduction hole 17p and a second gas introduction hole 17q leading, respectively, to the first and second gas pipe connecting sections 18p, 18q. The first gas pipe connecting section 18p leads to the gas source 20 via the upper-side gas pipe 19p, and a valve 21p capable of adjusting the flow of cooling gas is interposed in the upper-side gas pipe 19p. The second gas pipe connecting section 18q leads to the gas source 20 via the lower-side gas pipe 19q, and a valve 21q capable of adjusting the flow of cooling gas is interposed in the lower-side gas pipe 19q.

The first gas introduction hole 17p and the second gas introduction hole 17q lead, respectively, to the upper-side outlet ports 54C and the lower-side outlet ports 64C of the conduit block 40C. That is, the cooling gas supplied from the gas source 20 via the upper-side gas pipe 19p is output from the upper-side outlet ports 54C to generate the upper-side flow Fa, and the cooling gas supplied from the gas source 20 via the lower-side gas pipe 19q is output from the lower-side outlet ports 64C to generate the lower-side flow Fb. As above, the substrate cooling device 10C according to the third embodiment is configured such that the cooling gas for generating the upper-side flow Fa and the lower-side flow Fb is supplied from the single source 20 separately via the upper-side gas pipe 19p and the lower-side gas pipe 19q, respectively.

Alternatively, in some embodiments, two gas sources may be used. In such a configuration, one of the gas sources may be connected to the upper-side gas pipe 19p, and the other gas source may be connected to the lower-side gas pipe 19q. That is, different gas sources may supply the same cooling gas to flow through the two gas introduction holes Up, 17q of cover member 30C, respectively. In some embodiments, it may be possible alternatively to supply different gasses to the first gas introduction hole 17p and the second gas introduction hole 17q.

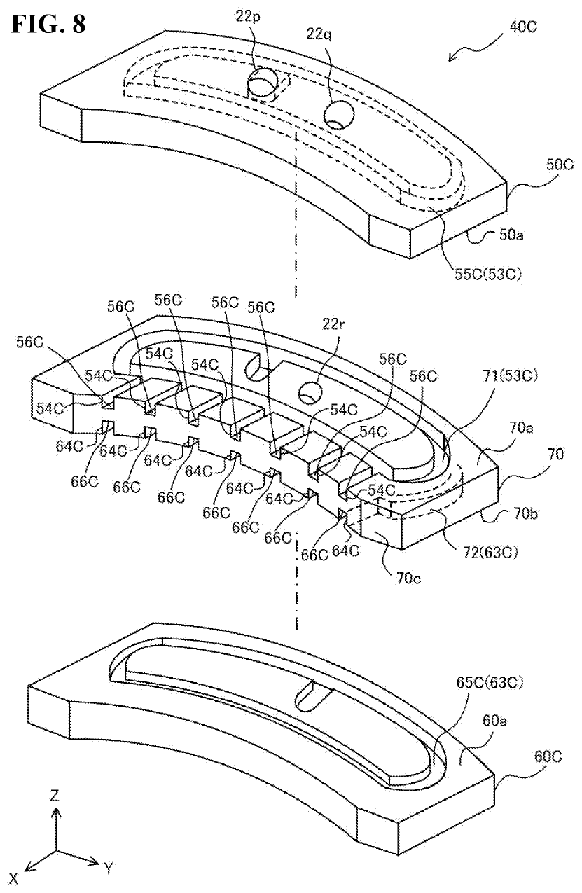

FIG. 8 is an exploded perspective view of the conduit block 40C.

As shown in FIG. 8, a lower surface 50a of the upper-side flow passage member 50C may be formed with an upper-side first groove portion 55C for allowing the first cooling gas for generating the upper-side flow Fa to flow therethrough, as indicated by the broken lines. Further, an upper surface 60a of the lower-side flow passage member 60C may be formed with a lower-side first groove portion 65C for allowing the second cooling gas for generating the lower-side flow Fb to flow therethrough.

An upper surface 70a of the intermediate member 70 may be formed with an upper-side second groove portion 71 for allowing the first cooling gas for generating the upper-side flow Fa to flow therethrough, and a lower surface 70b of the intermediate member 70 may be formed with a lower-side second groove portion 72 for allowing the second cooling gas for generating the lower-side flow Fb to flow therethrough, as indicated by the broken lines. Further, the upper-side outlet ports 54C are formed in a region of a front side surface 70c of the intermediate member 70 on the side of the upper surface 70a, and the lower-side outlet ports 64C are formed in a region of the front side surface 70c on the side of the lower surface 70b. Each of the upper-side outlet ports 54C and each of the lower-side outlet ports 64C may be formed in a concave shape opened, respectively, toward the upper surface 70a and the lower surface 70b, in front view.

In a state in which the upper-side flow passage member 50C, the intermediate member 70 and the lower-side flow passage member 60C are stacked and assembled into the conduit block 40C, the upper-side first groove portion 55C of the upper-side flow passage member 50C and the upper-side second groove portion 71 of the intermediate member 70 are joined together and closed mutually to create an upper-side flow passage 53C for allowing the first cooling gas for generating the upper-side flow Fa to flow therethrough. Similarly, the lower-side first groove portion 65C of the lower-side flow passage member 60C and the lower-side second groove portion 72 of the intermediate member 70 are joined together and closed mutually to create a lower-side flow passage 63C for allowing the second cooling gas for generating the lower-side flow Fb to flow therethrough. Here, the upper-side flow passage 53C and the lower-side flow passage 63C are formed without intersecting each other in the inside of the conduit block 40C.

The upper ends of the upper-side outlet ports 54C of the intermediate member 70 are closed by the lower surface 50a of the upper-side flow passage member 50C. Thus, the periphery of each of the upper-side outlet ports 54C is closed in the front-rear direction, so that it becomes possible for the first cooling gas to flow frontwardly. Similarly, the lower ends of the lower-side outlet ports 64C of the intermediate member 70 are closed by the upper surface 60a of the lower-side flow passage member 60C. Thus, the periphery of each of the lower-side outlet ports 64C is closed in the front-rear direction, so that it becomes possible for the second cooling gas to flow frontwardly (X-direction).

In the third embodiment, the upper-side flow passage member 50C and the lower-side flow passage member 60C are formed with the upper-side first groove portion 55C and the lower-side first groove portion 65C, respectively. However, in some embodiments, the upper-side first groove portion 55C and the lower-side first groove portion 65C may be omitted. That is, each of the lower surface 50a of the upper-side flow passage member 50C and the upper surface 60a of the lower-side flow passage member 60C may be formed in a flat shape, and configured to simply close a corresponding one of the upper-side second groove portion 71 and the lower-side second groove portion 72 each formed in the intermediate member 70. That is, each of the upper-side flow passage member 50C and the lower-side flow passage member 60C needs not necessarily be formed with a flow passage, but may be configured to make up a part of a corresponding one of the upper-side flow passage 53C and the lower-side flow passage 63C when the conduit block 40C is assembled.

The conduit block 40C may be regarded as being configured to create the upper-side flow passage 53C and the lower-side flow passage 63C by combining the upper-side flow passage member 50C, the intermediate member 70 and the lower-side flow passage member 60C together. That is, in the substrate cooling device 10C according to the third embodiment, the upper-side flow passage 53C and the lower-side flow passage 63C may be created by combining t the upper-side flow passage member 50C, the intermediate member 70 and the lower-side flow passage member 60C together, so that it becomes possible to facilitate the formation of the gas flow passage, and form a more complicated gas flow passage.

As shown in FIG. 7, the spacer member 80 may be formed with a first through-hole 80p and a second through-hole 80q penetrating therethrough in the thickness direction (Z-direction) and leading, respectively, to the first gas introduction hole 17p and the second gas introduction hole 17q.

Further, as shown in FIG. 8, the upper-side flow passage member 50C may be formed with a first through-hole 22p and a second through-hole 22q leading, respectively, to the first gas introduction hole 17p and the second gas introduction hole 17q. Further, the intermediate member 70 may be formed with a through-hole 22r leading to the second through-hole 19q and the second gas introduction hole 17q.

In a state in which the conduit block 40C is attached to the cover member 30C, the first gas introduction hole 17p leads to the upper-side flow passage 53C via the first through-hole 80p and the first through-hole 22p. Further, the second gas introduction hole 17q leads to the lower-side flow passage 63C via the second through-hole 80q, the second through-hole 22q and the through-hole 22r.

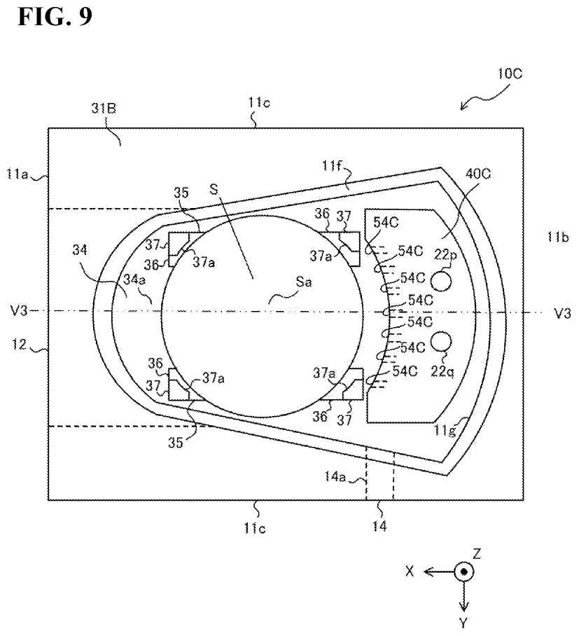

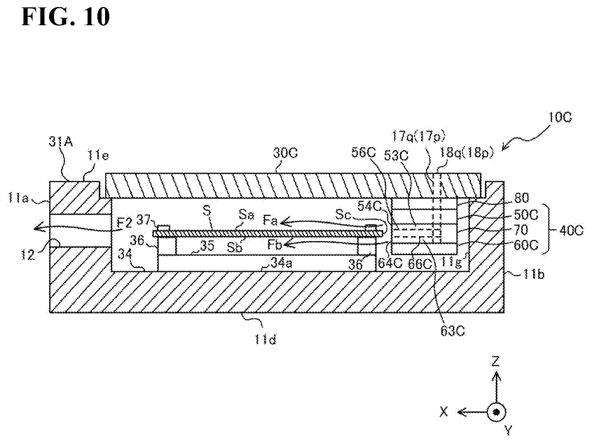

FIG. 9 is a top view of the substrate cooling device 30C in a state in which the cover member 30C is detached therefrom and in which the spacer member 80 is omitted. FIG. 10 is a vertical sectional view of the substrate cooling device 30C, taken along the line V3-V3 in FIG. 9. Whereas the cover member 30C is omitted in FIG. 9, it is shown in FIG. 10. As shown in FIG. 9, the upper-side outlet ports 54C of the conduit block 40C are arranged at even intervals in the right-left direction (Y-direction), and configured to uniformly output the cooling gas over the entire region of the upper surface Sa of the substrate S in the right-left direction. Further, as shown in FIGS. 7 and 8, the lower-side outlet ports 64C are arranged at the same positions as respective ones of the upper-side outlet ports 54C in the right-left direction (Y-direction), and configured to uniformly output the second cooling gas over the entire region of the lower surface Sb of the substrate S in the right-left direction.

As shown in FIG. 10, the set of upper-side outlet ports 54C and the set of lower-side outlet ports 64C are positioned to be spaced apart from each other in a thickness direction (Z-direction) of the substitute S, i.e., in the up-down direction, by a given distance across the substrate S. The upper-side outlet ports 54C output the cooling gas supplied from the gas source 20 via the upper-side gas pipe 19p, frontwardly (X-direction) toward the upper surface Sa of the substrate S housed in the housing space 34, to generate the upper-side flow Fa flowing on the upper surface Sa. Further, the lower-side outlet ports 64C output the cooling gas supplied from the gas source 20 via the lower-side gas pipe 19q, frontwardly (X-direction) toward the lower surface Sb of the substrate S housed in the housing space 34, to generate the lower-side flow Fb flowing on the lower surface Sb.

Differently from the substrate cooling device 10A according to the first embodiment and the substrate cooling device 10B according to the second embodiment, the substrate cooling device 10C according to the third embodiment is configured such that each of the upper-side flow Fa and the lower-side flow Fb generated frontwardly (X-direction) from a corresponding one of the plurality of upper-side outlet ports 54C and the plurality of lower-side outlet ports 64C in one direction flows on a corresponding one of an upper surface Sa side and a rear surface Sb side of the substrate S in the one direction without any branching. That is, by positioning the set of the plurality of upper-side outlet ports 54C and the set of the plurality of lower-side outlet ports 64C to be spaced apart from each other in the up-down direction (Z-direction) by a given distance across the substrate S, it becomes possible to generate, directly from the set of the plurality of upper-side outlet ports 54C and the set of the plurality of lower-side outlet ports 64C, the upper-side flow Fa and the lower-side flow Fb each flowing on a corresponding one of the upper surface Sa and the rear surface Sb of the substrate S in one direction without being branched by a side surface Sc of the substrate S.

In the substrate cooling device 10C according to the third embodiment, it is possible to generate each of the upper-side flow Fa and the lower-side flow Fb from a corresponding one of the set of the plurality of upper-side outlet ports 54C and the set of the plurality of lower-side outlet ports 64C, independently. Further, each of the flow volume or flow velocity of the cooling gas to be supplied to the set of the plurality of upper-side outlet ports 54C and the flow volume or flow velocity of the cooling gas to be supplied to the set of the plurality of lower-side outlet ports 64C may be controlled independently by controlling a corresponding one of the valve 21p and the valve 21q interposed respectively in the upper-side gas pipe 19p and the lower-side gas pipe 19q, independently, so that it is possible to control each of the flow volume or flow velocity of the upper-side flow Fa and the flow volume or flow velocity of the lower-side flow Fb, independently. Thus, by adjusting the flow of the cooling gas to each of the set of the plurality of upper-side outlet ports 54C and to the set of the plurality of lower-side outlet ports 64C, independently, it becomes possible to adjust each of the upper-side flow Fa and the lower-side flow Fb, independently, and thus more uniformly cool the substrate S.

Moreover, in addition to adjusting the flow via the valves 21p, 21q, each of the set of the plurality of upper-side outlet ports 54C and the set of the plurality of lower-side outlet ports 64C may be adjusted independently to suppress the occurrence of a difference in the progress of cooling between the upper surface Sa and the lower surface Sb of the substrate S in the one direction (X-direction), such as adjusting each of the set of the plurality of upper-side outlet ports 54C and the set of the plurality of lower-side outlet ports 64C, independently, and/or each of the upper-side outlet ports 54C and the lower-side outlet ports 64C independently, in terms of the shape and/or area of the outlet ports 54C, 64C, and/or changing an output direction of the cooling gas being output from the outlet ports 54C and 64C.

Particularly in the substrate cooling device 10C according to the third embodiment, the upper-side flow passage 53C and the lower-side flow passage 63C are formed without intersecting each other. Thus, each of the flow volume or flow velocity of the cooling gas to be supplied to the set of the plurality of upper-side outlet ports 54C and the flow volume or flow velocity of the second cooling gas to be supplied to the set of the plurality of lower-side outlet ports 64C may be controlled independently by controlling each of the valve 21p and the valve 21q respectively interposed in the upper-side gas pipe 19p and the lower-side gas pipe 19q, independently. Therefore, each of the flow volume or flow velocity of the first cooling gas to be output from the set of the plurality of upper-side outlet ports 54C and the flow volume or flow velocity of the second cooling gas to be output from the set of the plurality of lower-side outlet ports 64C may be controlled independently, so that it is possible to adjust each of the flow volume or flow velocity of the upper-side flow Fa and the flow volume or flow velocity of the lower-side flow Fb, independently. Accordingly, with regard to each of the upper-side flow Fa and the lower-side flow Fb, one or both of the flow velocity and flow volume may be adjusted. This configuration makes it possible to more reliably adjust each of the upper-side flow Fa and the lower-side flow Fb, independently, and thus more reliably suppress the occurrence of the difference in the progress of cooling between the upper surface Sa and the lower surface Sb of the substrate S in the one direction, thereby more uniformly cooling the substrate S.

The plurality of upper-side outlet ports 54C and the plurality of lower-side outlet ports 64C may be arranged alternately in the right-left direction (Y-direction). Further, at least one of the set of the plurality of upper-side outlet ports 54C and the set of the plurality of lower-side outlet ports 64C may be configured to output the cooling gas toward the substrate S in a direction inclined in the up-down direction (Z-direction) with respect to the right-left direction (Y-direction). Further, the position of each of the set of the plurality of upper-side outlet ports 54C and the set of the plurality of lower-side outlet ports 64C in the up-down direction (Z-direction) with respect to the substrate S may be changed by changing the thicknesses of the spacer member 80 and the intermediate member 70.

It should be noted that the spacer member 80 is used to adjust an up-down directional position of each of the set of the plurality of upper-side outlet ports 54C and the set of the plurality of lower-side outlet ports 64C with respect to the substrate S, and in some embodiments, the spacer member 80 may be omitted.

As shown in FIG. 8, the intermediate member 70 of the conduit block 40C is formed with an upper-side restriction surface 56C continuing to the upper-side outlet ports 54C. As shown in FIGS. 8 and 10, the upper-side restriction surface 56C is formed as a bottom surface of the upper-side flow passage 53C continuing to the upper-side outlet ports 54C. Similarly, as shown in FIG. 8, the intermediate member 70 of the conduit block 40C is formed with a lower-side restriction surface 66C continuing to the lower-side outlet ports 64C. As shown in FIGS. 8 and 10, the lower-side restriction surface 66C is formed as a top surface of the lower-side flow passage 63C continuing to the lower-side outlet ports 64C.

The upper-side restriction surface 56C is configured to restrict the occurrence of a situation where the cooling gas output from the upper-side outlet ports 54C collides with the side surface Sc of the substrate S, thereby guiding the cooling gas to reliably flow toward the upper surface Sa side of the substrate S. Similarly, the lower-side restriction surface 66C is configured to restrict the occurrence of a situation where the cooling gas output from the lower-side outlet ports 64C collides with the side surface Sc of the substrate S, thereby guiding the cooling gas to reliably flow toward the lower surface Sb side of the substrate S.

In the substrate cooling device 10C according to the third embodiment, the conduit block 40C comprises the upper-side restriction surface 56C and the lower-side restriction surface 66C, so that it is possible to restrict the occurrence of the situation where the cooling gas immediately after being output from each of the set of the plurality of upper-side outlet ports 54C and the set of the plurality of lower-side outlet ports 64C collides with the side surface Sc of the substrate S. Thus, even when the flow volume or flow velocity of the cooling gas to be output from each of the set of the plurality of upper-side outlet ports 54C and the set of the plurality of lower-side outlet ports 64C is increased, there is no possibility of the occurrence of displacement of the substrate S which may be caused by a phenomenon that the side surface Sc of the substrate S is pushed by the cooling gas. Therefore, it becomes possible to increase the flow volume or flow velocity of each of the upper-side flow Fa and the lower-side flow Fb, without taking into account the occurrence of displacement of the substrate S, thereby shortening a time period for cooling the substrate S down to a given temperature.

Here, each of the upper-side restriction surface 56C and the lower-side restriction surface 66C needs not to necessarily be capable of completely preventing the cooling gas from colliding with the side surface Sc of the substrate S, but may suppress the collision to the extent that no displacement of the substrate S occurs.

In the substrate cooling device 10C according to the third embodiment, the flows output from the set of the plurality of upper-side outlet ports 54C and the set of the plurality of lower-side outlet ports 64C may be more spread out since the set of the plurality of upper-side outlet ports 54C and the set of the plurality of lower-side outlet ports 64C of the conduit block 40C are set closer to the side surface Sc of the substrate S. In this case, it is possible to allow the cooling gas to flow on the upper surface Sa and the lower surface Sb of the substrate S without colliding with the side surface of the substrate S, thereby improving cooling efficiency. In other words, the cooling efficiency may be improved by replacing the conduit block 40C with another conduit block 40C having a different position of each of the set of the plurality of upper-side outlet ports and the set of the plurality of lower-side outlet ports set closer to the side surface Sc of the substrate S.

A conduit block 40D as a modification of the conduit block 40C in the third embodiment will be described. The conduit block 40D is configured to be replaceable with the aforementioned conduit block 40C and used in the substrate cooling device 10C. Since the usage of conduit block 40D is identical to that of the conduit block 40C, a repeated description of the usage will be omitted for conciseness. Thus, the following description will be made about a configurations unique to the conduit block 40D and functions/effects thereof

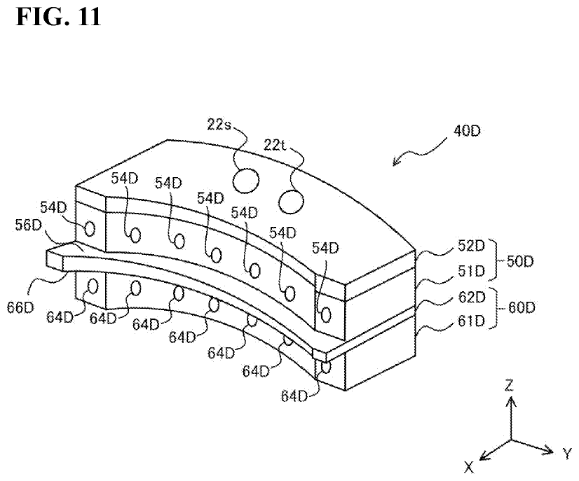

FIG. 11 is a perspective view showing the conduit block 40D.

The conduit block 40D may be used in a state in which the conduit block 40D is attached to the cover member 30C, and constructed by assembling an upper-side flow passage member 50D and a lower-side flow passage member 60D such that the upper-side flow passage member 50D and the lower-side flow passage member 60D are stacked in the up-down direction. The upper-side flow passage member 50D has a plurality of upper-side outlet ports 54D for generating the upper-side flow Fa flowing on the upper surface Sa of the substrate S housed in the housing space 34. The lower-side flow passage member 60D has a plurality of lower-side outlet ports 64D for generating the lower-side flow Fb flowing on the lower surface Sb of the substrate S housed in the housing space 34. While seven upper-side outlet ports 54D and seven lower-side outlet ports 64D are illustrated in FIG. 11, this is only an example and, in some embodiments, fewer or more than seven upper-side outlet ports 54D may be provided and fewer or more than seven lower-side outlet ports 64D may be provided. In this modification, the shape of each open end of the upper-side outlet ports 54D and the lower-side outlet ports 64D may be a round shape. However, the shape is not limited to round shape, and, in some embodiments, the shape may be any other suitable shape such as a rectangular shape.

The conduit block 40D is configured such that, in the state in which the conduit block 40D is attached to the cover member 30C, the upper-side outlet ports 54D of the upper-side flow passage member 50D lead to the first gas introduction hole 17p of the cover member 30C, and similarly the lower-side outlet ports 64D of the lower-side flow passage member 60D lead to the second gas introduction hole 17q of the cover member 30C. That is, the conduit block 40D is also configured such that the upper-side flow Fa and the lower-side flow Fb are generated by the cooling gas supplied such that gas from the single gas source 20 is branched halfway.

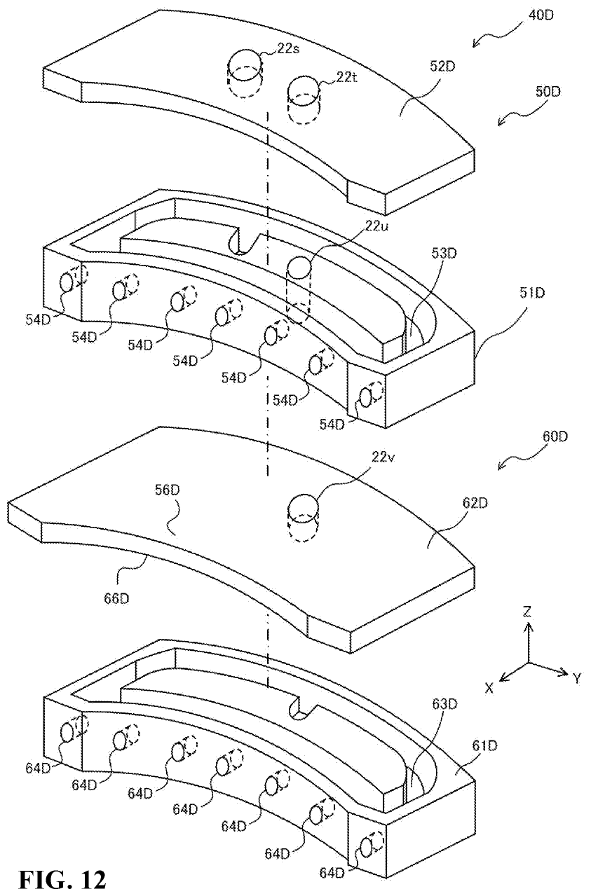

FIG. 12 is an exploded perspective view of the conduit block 40D.

As shown in FIG. 12, the upper-side flow passage member 50D comprises an upper-side body portion 51D and an upper-side lid portion 52D. The upper-side body portion MD is formed with an upper-side flow passage 53D for allowing the cooling gas for generating the upper-side flow Fa to flow therethrough, wherein the upper-side flow passage 53D is formed from a groove and a through-hole leading to the outlet ports 54D. The upper-side lid portion 52D closes an open end of the upper-side body portion MD. The upper-side flow passage 53D is created as a flow passage after a groove formed in the upper-side body portion 51D is closed by the upper-side lid portion 52D. The lower-side flow passage member 60D comprises a lower-side body portion 61D and a lower-side lid portion 52D. The lower-side body portion 61D is formed with a lower-side flow passage 63D for allowing the cooling gas for generating the lower-side flow Fb to flow therethrough, wherein the lower-side flow passage 63D is formed from a groove and a through-hole leading to the outlet ports 64D. The lower-side lid portion 62D closes an open end of the lower-side body portion 61D. The lower-side flow passage 63D is created as a flow passage after a groove formed in the lower-side body portion 61D is closed by the lower-side lid portion 62D. The upper-side flow passage 53D and the lower-side flow passage 63D may be formed without intersecting each other.

The upper-side flow passage member 50D may be regarded as being configured to create the upper-side flow passage 53B by combining the upper-side body portion 51D and the upper-side lid portion 52D together. Similarly, the lower-side flow passage member 60D may be regarded as being configured to create the lower-side flow passage 53D by combining the lower-side body portion 61D and the lower-side lid portion 62D together.

Further, the conduit block 40D may be regarded as being configured to create a gas flow passage for allowing the cooling gas to flow therethrough, by combining the upper-side flow passage member 50D and the lower-side flow passage member 60D together. The conduit block 40D may also be regarded as being configured to create a gas flow passage for allowing the cooling gas to flow therethrough, by combining the upper-side body portion 51D, the upper-side lid portion 52D, the lower-side body portion 61D and the lower-side lid portion 62D together.

In some embodiments, a sealing member may be provided. The upper-side body portion 51D, the upper-side lid portion 52D, the lower-side body portion 61D and the lower-side lid portion 62D may be assembled together while the sealing member such as packing is interposed between adjacent thereof. Further, any one or each of the upper-side body portion 51D, the upper-side lid portion 52D, the lower-side body portion 61D and the lower-side lid portion 62D may be composed of a plurality of bodies.

As shown in FIG. 12, the upper-side lid portion 52D is formed with a first through-hole 22s and a second through-hole 22t each leading to a corresponding one of the first gas introduction hole 17p and the second gas introduction hole 17q. Further, the upper-side body portion MD and the lower-side lid portion 62D are formed, respectively, with a through-hole 22u and a through-hole 22v each leading to the second through-hole 22t and the second gas introduction hole 17q. In the state in which the conduit block 40D is attached to the cover member 30D, the first gas introduction hole 17p leads to the upper-side flow passage 53D via the first through-hole 22s. Further, the second gas introduction hole 17q leads to the lower-side flow passage 63D via the second through-hole 22t, the through-hole 22u, and the through-hole 22v.

As shown in FIGS. 11-12, the upper-side outlet ports 54D of the conduit block 40D are arranged at even intervals in the right-left direction (Y-direction), and configured to uniformly output the cooling gas over the entire region of the upper surface Sa of the substrate S in the right-left direction. Further, as shown in FIGS. 11-12, the lower-side outlet ports 64D are arranged at the same positions as respective ones of the upper-side outlet ports 54D in the right-left direction (Y-direction), and configured to uniformly output the cooling gas over the entire region of the lower surface Sb of the substrate S in the right-left direction.

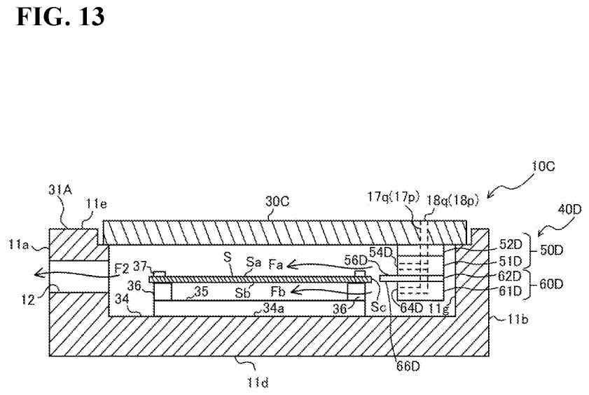

FIG. 13 is a sectional view of the substrate cooling device 30C using the conduit block 40D. Here, a cutting position of the cross-section in FIG. 13 is the same as that in the cross-sectional view of FIG. 10.

As shown in FIG. 13, the set of the plurality of upper-side outlet ports 54D and the set of the plurality of lower-side outlet ports 64D are positioned to be spaced apart from each other in the thickness direction (Z-direction) of the substitute S, i.e., in the up-down direction, by a given distance across the substrate S. The upper-side outlet ports 54D output the cooling gas supplied from the gas source 20 via the upper-side gas pipe 19p, toward the upper surface Sa of the substrate S housed in the housing space 34, to generate the upper-side flow Fa flowing on the upper surface Sa. Further, the lower-side outlet ports 64D output the cooling gas supplied from the gas source 20 via the lower-side gas pipe 19q, toward the lower surface Sb of the substrate S housed in the housing space 34, to generate the lower-side flow Fb flowing on the lower surface Sb.

As shown in FIGS. 11 and 13, the lower-side lid portion 62D has an upper-side restriction surface 56D for restricting the occurrence of a situation where the cooling gas immediately after being output from the upper-side outlet ports 54D collides with the side surface Sc of the substrate S, and a lower-side restriction surface 66D for restricting the occurrence of a situation where the cooling gas immediately after being output from the lower-side outlet ports 64D collides with the side surface Sc of the substrate S. The upper-side restriction surface 56D and the lower-side restriction surface 66D are formed to serve, respectively, as an upper surface and a rear surface of the lower-side lid portion 62D. Each of the upper-side restriction surface 56D and the lower-side restriction surface 66D may be formed to extend frontwardly (X-direction) beyond the upper-side outlet ports 54D and the lower-side outlet ports 64D.

As shown in FIG. 13, the lower-side lid portion 62D is disposed to be opposed to the side surface Sc of the substrate S at approximately the same position as the side surface Sc of the substrate S in the up-down direction (Z-direction). Thus, the cooling gas immediately after being output from the upper-side outlet ports 54D is restricted in terms of flow direction by the upper-side restriction surface 56D, and therefore collision with the side surface Sc of the substrate S is suppressed. Similarly, the cooling gas immediately after being output from the lower-side outlet ports 64D is restricted in terms of flow direction by the lower-side restriction surface 66D, and therefore collision with the side surface Sc of the substrate S is suppressed.

That is, in the conduit block 40D, by providing the upper-side restriction surface 56D, cooling gas is prevented from pushing the side surface Sc of the substrate S immediately after being output from the upper-side outlet ports 54D. Further, by providing the lower-side restriction surface 66D, the cooling gas is prevented form pushing the side surface Sc of the substrate S immediately after being output from the lower-side outlet ports 64D. Thus, even when the flow volume or flow velocity of the cooling gas to be output from each of the set of the plurality of upper-side outlet ports 54D and the set of the plurality of lower-side outlet ports 64D is increased, the phenomenon that the side surface Sc of the substrate S is pushed by the cooling gas is suppressed. Therefore, it becomes possible to increase the flow volume or flow velocity of each of the upper-side flow Fa and the lower-side flow Fb, without taking into account the occurrence of displacement of the substrate S, thereby shortening a time period for cooling the substrate S down to a given temperature.

In this modification, the lower-side lid portion 62D is configured to have the upper-side restriction surface 56D and the lower-side restriction surface 66D. Alternatively, in some embodiments, a plate member may be prepared separately from the lower-side lid portion 62D, and the upper-side restriction surface 56D the lower-side restriction surface 66D may be formed in the plate member. In this case, the plate member is not limited to a single plate member, but may be composed of two plate members formed, respectively, with the upper-side restriction surface 56D the lower-side restriction surface 66D.

According to an aspect of one or more embodiments, there is provided a substrate cooling device which comprises a device body internally formed with a housing space for housing a substrate, wherein the substrate cooling device is configured to introduce a cooling gas into the housing space to cool the substrate housed in the housing space. The substrate cooling device is characterized in that it comprises a conduit block having a gas flow passage which allows the cooling gas to flow therethrough, and an outlet port leading to the gas flow passage and configured to output the cooling gas such that the cooling gas flows on an upper surface and a lower surface of the substrate in one direction; and a discharge portion positioned in opposed relation to the outlet port, across the substrate housed in the housing space, and configured to discharge the cooling gas from the housing space in the one direction, wherein the conduit block is configured such that at least a part of the conduit block is removable to an outside of the device body.

In the substrate cooling device having the above feature, the cooling gas output from the outlet port toward the substrate housed in the housing space flows on each of the upper surface and the lower surface of the substrate in the one direction, and is then discharged from the discharge portion in the one direction. That is, the cooling gas output from the outlet port is discharged from the discharge portion after flowing on the upper surface and the lower surface of the substrate, in the one direction on a continuous basis. Thus, each of an upper surface side and a lower surface side of the substrate will be sequentially cooled from a region closer to the outlet port, so that it is possible to suppress a situation where a difference in the progress of cooling in the one direction occurs between the upper surface side and the lower surface side of the substrate. Therefore, it becomes possible to uniformly cool the substrate by the cooling gas.

In the substrate cooling device, the conduit block may be configured such that at least a part of the conduit block is removable to the outside of the device body, so that at least a part of a plurality of constituent members of the conduit block or the entirety of the conduit block may be removed to the outside of the device body to perform maintenance work such as cleaning. Therefore, as comparted to a case where the conduit block is integrally formed with the device body, work efficiency during maintenance is improved.

Further, in the case that the conduit block is configured to be integrally formed with the device body and it is desired to modify the shape of the outlet port or the gas flow passage, it is necessary to replace the entire device body. On the other hand, in the substrate cooling device having the above configuration, the entirety of or a part of the conduit block may be replaced with a new one formed with an outlet port or gas flow passage subjected to a desired modification. Therefore, it is possible to easily modify the configuration of the outlet port or the gas flow passage.

In the substrate cooling device, a first flow may be branched into an upper-side flow which flows on the upper surface and a lower-side flow which flows on the lower surface, wherein the first flow may be a flow of the cooling gas immediately after being output from the outlet port.

According to this configuration, the first flow of the cooling gas output from the outlet port is branched into the upper-side flow and the lower-side flow flowing on the upper surface and the lower surface of the substrate, respectively. Thus, it is not necessary to divide the gas flow passage formed in the conduit block, into a flow passage for a cooling gas flowing along the upper surface side, and a flow passage for a cooling gas flowing along the lower surface side. That is, the conduit block may be formed with a simple configuration.

In the above substrate cooling device, the outlet port may be positioned in opposed relation to a side surface of the substrate housed in the housing space, wherein the first flow is branched into the upper-side flow and the lower-side flow by the side surface.

According to this configuration, the first flow may be branched into the upper-side flow and the lower-side flow by the side surface of the substrate housed in the housing space, so that it is not necessary to additionally provide a configuration for branching the first flow into the upper-side flow and the lower-side flow.

In the substrate cooling device, the conduit block may include a plurality of divided bodies, wherein the gas flow passage is formed by combining at least two of the divided bodies.

According to this configuration, the gas flow passage may be created by combining the divided bodies, so that it becomes possible to facilitate the formation of the gas flow passage, and form a more complicated gas flow passage.

In the substrate cooling device, the outlet port may include at least one upper-side outlet port for generating an upper-side flow which is a flow of the cooling gas flowing on the upper surface, and at least one lower-side outlet port for generating a lower-side flow which is a flow of the cooling gas flowing on the lower surface, wherein the upper-side outlet port and the lower-side outlet port are positioned, respectively, on an upper side and a lower side of the substrate with respect to a thickness direction of the substrate housed in the housing space.

According to this configuration, the upper-side outlet port for generating the upper-side flow and the lower-side outlet port for generating the lower-side flow are positioned, respectively, on the upper side and the lower side of the substrate with respect to the thickness direction of the substrate housed in the housing space, so that it is possible to generate each of the upper-side flow and the lower-side flow, independently. Thus, each of the upper-side flow and the lower-side flow may be adjusted independently, and thus it is possible to more reliably suppress the occurrence of the difference in the progress of cooling between the upper surface side and the lower surface side of the substrate. Therefore, it becomes possible to more uniformly cool the substrate.

In the above substrate cooling device, the conduit block may have an upper-side restriction surface for restricting an occurrence of a situation where the cooling gas output from the upper-side outlet port collides with a side surface of the substrate, and a lower-side restriction surface for restricting an occurrence of a situation where the cooling gas output from the lower-side outlet port collides with the side surface of the substrate.

According to this configuration, the upper-side restriction surface is provided to restrict the occurrence of the situation where the cooling gas output from the upper-side outlet port collides with the side surface of the substrate. Further, the lower-side restriction surface is provided to restrict the occurrence of the situation where the cooling gas output from the lower-side outlet port collides with the side surface of the substrate. Thus, even when the flow volume or flow velocity of the cooling gas output from each of the upper-side outlet port and the lower-side outlet port is increased, it is possible to suppress a situation where the side surface of the substrate is pushed by the cooling gas. Therefore, it becomes possible to increase the flow volume or flow velocity of each of the upper-side flow and the lower-side flow, without taking into account the occurrence of displacement of the substrate, thereby shortening a time period for cooling the substrate down to a given temperature.

In the above substrate cooling device, the gas flow passage may include an upper-side flow passage leading to the upper-side outlet port, and a lower-side flow passage leading to the lower-side outlet port, wherein the conduit block may include a plurality of divided bodies, and wherein at least one of the upper-side flow passage and the lower-side flow passage is created by combining at least two of the divided bodies.

According to this configuration, at least one of the upper-side flow passage and the lower-side flow passage may be created by combining the divided bodies, so that it becomes possible to facilitate the formation of the gas flow passage, and form a more complicated gas flow passage.

In the above substrate cooling device, the gas flow passage may include an upper-side flow passage leading to the upper-side outlet port, and a lower-side flow passage leading to the lower-side outlet port, wherein the upper-side flow passage and the lower-side flow passage are formed without intersecting each other.

According to this configuration, the upper-side flow passage and the lower-side flow passage are formed without intersecting each other, so that each of the flow volume or flow velocity of the cooling gas flowing through the upper-side flow passage and the flow volume or flow velocity of the cooling gas flowing through the lower-side flow passage may be controlled independently. Therefore, by controlling each of the flow volume or flow velocity of the cooling gas to be output from the upper-side flow passage and the flow volume or flow velocity of the cooling gas to be output from the lower-side flow passage independently, it becomes possible to adjust each of the flow volume or flow velocity of the upper-side flow and the flow volume or flow velocity of the lower-side flow, independently.

The substrate cooling device according to various embodiments discussed above may uniformly cool the substrate by the cooling gas.

While example embodiments have been illustrated and described above, it will be apparent to those skilled in the art that modifications and variations could be made without departing from the scope defined by the appended claims.

What is claimed is:

1. A substrate cooling device comprising:
a device body having internally formed therein a housing space configured to house a substrate, the device body having a discharge portion formed therein; and
a conduit block comprising a gas flow passage through which a cooling gas flows into the housing space, and an outlet port leading to the gas flow passage, the conduit block being configured to output the cooling gas such that the cooling gas flows along an upper surface of the substrate in one direction and along a lower surface of the substrate in the one direction,
wherein the discharge portion is positioned across the substrate in opposed relation to the outlet port, and the cooling gas is discharged in the one direction from the housing space through the discharge portion.

2. The substrate cooling device as recited in claim 1, wherein the conduit block is configured such that at least a part of the conduit block is removable from the device body.

3. The substrate cooling device as recited in claim 1, wherein a flow of the cooling gas after being output from the outlet port branches into an upper-side flow which flows on the upper surface and a lower-side flow which flows on the lower surface.

4. The substrate cooling device as recited in claim 3, wherein the outlet port is positioned at a same level as a side surface of the substrate housed in the housing space, and wherein the flow of the cooling gas is branched into the upper-side flow and the lower-side flow by the side surface.

5. The substrate cooling device as recited in claim 1, wherein the conduit block comprises a plurality of bodies, and wherein the gas flow passage is formed by combining the plurality of bodies.

6. The substrate cooling device as recited in claim 1, wherein the outlet port comprises at least one upper-side outlet port that provides an upper-side flow of the cooling gas along the upper surface of the substrate, and at least one lower-side outlet port that provides a lower-side flow of the cooling gas along the lower surface of the substrate, wherein the upper-side outlet port and the lower-side outlet port are positioned, respectively, on an upper side and a lower side of the substrate in a thickness direction orthogonal to the upper surface of substrate housed in the housing space.

7. The substrate cooling device as recited in claim 6, wherein the conduit block has an upper-side restriction surface that restricts the cooling gas output from the upper-side outlet port from colliding with a side surface of the substrate, and a lower-side restriction surface that restricts the cooling gas output from the lower-side outlet port from colliding with the side surface of the substrate.

8. The substrate cooling device as recited in claim 5, wherein the gas flow passage includes an upper-side flow passage leading to the upper-side outlet port, and a lower-side flow passage leading to the lower-side outlet port.

9. The substrate cooling device as claimed in claim 8,
wherein the conduit block comprises a plurality of divided bodies, and
wherein at least one of the upper-side flow passage and the lower-side flow passage is formed by at least two of the divided bodies.

10. The substrate cooling device as recited in claim 8, wherein the upper-side flow passage and the lower-side flow do not intersect each other.

11. A substrate cooling device comprising:
a device body having a housing space, and a discharge portion for receiving and discharging a substrate into and out of the housing space;
a conduit block comprising an outlet port arranged in the device body across the housing space from the discharge portion, and a gas flow passage which is connected to the outlet port and configured to receive a cooling gas,
wherein the conduit block outputs the cooling gas from the outlet port across the housing space in one direction such that the cooling gas flows across an upper surface of the substrate in the one direction and across a lower surface of the substrate in the one direction.

12. The substrate cooling device as recited in claim 11, wherein the cooling gas is discharged from the device body in the one direction through the discharge portion.

13. The substrate cooling device as recited in claim 11, wherein the conduit block is configured such that at least a portion of the conduit block is removable from the device body.

14. The substrate cooling device as recited in claim 11, wherein a flow of the cooling gas after exiting the outlet port branches into an upper-side flow which flows across the upper surface and a lower-side flow which flows across the lower surface.

15. The substrate cooling device as recited in claim 14, wherein the outlet port is positioned at a same level as a side surface of the substrate when the substrate is received in the housing space, and
wherein a flow of the cooling gas after existing the outlet port is branched into the upper-side flow and the lower-side flow by the side surface of the substrate.

16. The substrate cooling device as recited in claim 11, wherein the conduit block comprises a plurality of bodies, and wherein the gas flow passage is formed by the plurality of bodies.

17. The substrate cooling device as recited in claim 11, wherein the outlet port comprises a plurality of outlet ports and the gas flow passage comprises a plurality of gas flow passages in communication with the plurality of outlet ports, respectively.

18. The substrate cooling device as recited in claim 17, wherein the plurality of outlet ports are arranged at a same height as the substrate received in the housing space.

19. The substrate cooling device as recited in claim 17, wherein a first portion of the plurality of outlet ports are arranged at a height above a height of the substrate received in the housing space, and a second portion of the plurality of outlet ports are arranged at a height below the height of the substrate.

20. A substrate cooling device comprising:
a device body having a housing space including a support portion for supporting a substrate therein, the device body having an opening in a wall surface thereof;
conduit block arranged in the device body across the housing space from the opening, the conduit block including a plurality of gas outlet ports and a gas flow passage in communication with the plurality of gas outlet ports, the gas flow passage configured to receive a cooling gas from outside of the substrate cooling device,
wherein the cooling gas flows from the plurality of gas outlet ports, across the housing space, and out the opening in one direction such that the cooling gas flows in the one direction across an upper surface of the substrate when the substrate is supported by the support portion and in the one direction across a lower surface of the substrate.
